(19) United States
(12) Patent Application Publication
(10) Pub. No.: US 2019/0090356 A1
(43) Pub. Date: Mar. 21, 2019

(54) PCB ASSEMBLY WITH FASTENERS

(71) Applicant: PHILIPS LIGHTING HOLDING B.V., EINDHOVEN (NL)

(72) Inventors: Peter Johannes Martinus BUKKEMS, EINDHOVEN (NL); Robertus Johannes Maria Mathilde SNIJKERS, EINDHOVEN (NL)

(73) Assignee: PHILIPS LIGHTING HOLDING B.V., EINDHOVEN (NL)

(21) Appl. No.: 16/082,178

(22) PCT Filed: Mar. 20, 2017
(86) PCT No.: PCT/EP2017/056508

§ 371 Date: Sep. 4, 2018

(30) Foreign Application Priority Data
Apr. 4, 2016 (EP) 16163624.6

(51) Int. Cl. H05K 3/36; H05K 1/14; H05K 3/00

(52) U.S. Cl. CPC H05K 3/368; H05K 1/144; H05K 3/0058; H05K 2201/1059; H05K 2201/10265; H05K 2201/10295; H05K 2201/041

(57) ABSTRACT

A PCB assembly comprising a PCB having a set of through holes, and at least one snap on fastener having an abutment portion connected to a fixating portion, the fixating portion having a protruding section which is compressible against a spring force, such that, when the fixating portion is introduced into said hole, the protruding section is compressed to pass through the hole and allowed to expand on an opposite side of the hole and snap fit in the hole, while the abutment portion abuts against a surface of the PCB. The invention provides a significantly more efficient mounting process. Also, the fasteners will typically allow dismounting, e.g. facilitating replacement of a PCB. Further, the snap-on fasteners provide a flexible connection, which allows thermal expansion of the support without straining or damaging the PCB.

### FIELD OF THE INVENTION

The present invention relates to a PCB assembly including a PCB and a plurality of fasteners.

### BACKGROUND OF THE INVENTION

There are numerous applications where different types of printed circuit boards (PCBs) are mounted on some type of support structure. One specific example are PCBs carrying LEDs, so called LED boards, which are mounted to a support (e.g. part of a luminaire). The support typically has a thickness in the same order as the PCB, i.e. a few millimeters.

Conventionally, PCBs are mounted with screws through holes provided in the PCB and the luminaire. These holes are described in a ZHAGA standard allowing competitors to mount their LED solution inside a luminaire. However, using screws requires significant handling. Generally, the process looks like this:
1. remove one PCB from a tray
2. pick one screw
3. put the screw on a screwdriver head or in a hole
4. position the PCB
5. make several turns of the screw (chance of damage)
6. until the right torque has been achieved.

This is done over and over again for all screw holes that are in this board system. This pattern could be extended multiple times and also multiplies the amount of screws.

In addition to being a time consuming process, the screws also provide a very static fixation of the PCB. In situations where the support is subject to temperature variations (e.g. caused by the LEDs) the shape or thickness of the support may change, leading to strain or even damage to the PCB.

### SUMMARY OF THE INVENTION

It is an object of the present invention to mitigate this problem, and to provide a more efficient and flexible way to attach the PCB to a support.

According to a first aspect of the invention, this and other objects are achieved by a PCB assembly comprising a PCB having a set of through holes, and at least one fastener configured to be introduced into one of said holes. The fastener is a snap on fastener having an abutment portion connected to a fixating portion, the fixating portion having a protruding section which is compressible against a spring force, wherein a distance between the abutment portion and the protruding section is larger than a thickness of the PCB, such that, when the fixating portion is introduced into said hole, the protruding section is compressed to pass through the hole and allowed to expand on an opposite side of the hole and snap fit in the hole, while the abutment portion abuts against a surface of the PCB.

With a PCB assembly that includes such a snap-on or click-on fastener, a significantly more efficient mounting process may be achieved. The fasteners are simply pressed into the holes and openings, immediately securing the PCB to the support. The assembly time may thus be shortened. Also, the fasteners will typically allow dismounting, e.g. facilitating replacement of a PCB. Further, the snap-on fasteners provide a flexible connection, which allows thermal expansion of the support without straining or damaging the PCB.

The holes in the PCB could be any type of holes, and may specifically (but not necessarily) be holes according to the ZHAGA standard. The PCB arrangement is thus compatible with existing luminaires as well as new luminaires. It is noted that one or several of the holes may be located at the outer edge of the PCB, so that these holes are open to one side.

The design of the fastener is preferably such that the force required to push the fastener into a hole is smaller than the force required to pull the fastener out of the same hole. This ensures a self-locking effect.

The PCB assembly may be attached to a support plate having a set of openings aligned with the holes in the PCB, wherein fasteners have been introduced into the holes and corresponding openings in the support, thereby securing the PCB to the support plate.

Each fastener may be pre-mounted in a hole. Hereby the PCB assembly is immediately ready to assemble, without picking up a plurality of small fasteners. The mounting is further simplified, as several fasteners can be attached at the same time.

Several PCB assemblies according to the present invention may be placed in a stack, including at least a first PCB assembly resting on a second PCB assembly, wherein a distal end of the fixating portion of each fastener of the first PCB assembly rests on the abutment portion of a corresponding fastener of the second PCB.

The fasteners provide a separation between the PCBs in the stack, such that components mounted on the PCBs, such as LEDs, are not damaged. As the PCBs can be stacked on top of each other, the PCBs can be stored without the need of a specific tray. More PCBs can thus be stored in the same volume.

According to a second aspect of the invention, the objects are achieved by a method for mounting a PCB to a support plate, the PCB having a set of through holes, and the support plate having a set of openings aligned with the holes in the PCB, the method comprising providing a set of snap-on fasteners, each fastener having an abutment portion connected to a fixating portion, the fixating portion having a protruding section which is compressible against a spring force, pre-mounting one of the fasteners in each hole in the PCB, by introduced the fixating portion into the hole such that the protruding section is compressed to pass through the hole and allowed to expand on an opposite side of the hole and snap fit in the hole, while the abutment portion abuts against a surface of the PCB, aligning each fastener with a corresponding opening in the support plate, and applying pressure on each fastener, such that the fixating portion is pressed through the opening in the support plate and allowed to expand on an opposite side of the opening and snap fit in the opening, thereby securing the PCB to the support plate.

The fasteners may be pre-mounted using a surface mounting technology (SMT) process. Such a process typically includes an automatic verification that every hole intended for a component has been used. Thereby, it is ensured that all fasteners have been mounted properly.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiments of the invention.

FIG. 1 is an exploded view of a PCB mounted to a support plate by means of fasteners according to an embodiment of the invention.

FIG. 2a shows a perspective view of a fastener according to a first embodiment of the invention.

FIG. 2b shows a perspective view of a fastener according to a second embodiment of the invention.

FIG. 3a shows in more detail a fastener as in FIG. 2a connecting a PCB to a support plate having a first thickness.

FIG. 3b shows in more detail a fastener as in FIG. 2a connecting a PCB to a support plate having a second thickness.

FIG. 4a shows in more detail a fastener as in FIG. 2a connecting a PCB to a support plate with a hole of a first diameter.

FIG. 4b shows in more detail a fastener as in FIG. 2a connecting a PCB to a support plate with a hole of a second diameter.

FIG. 5 shows schematically mounting a fastener to a PCB according to an embodiment the invention.

FIG. 6 shows a perspective view of a stack of PCBs provided with fasteners according to an embodiment of the invention.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

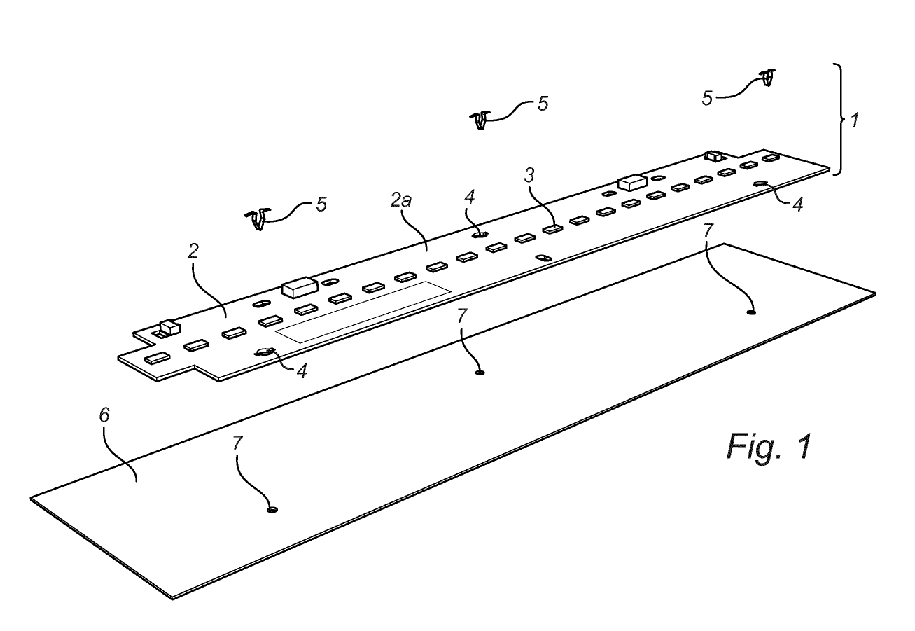

FIG. 1 shows schematically a PCB arrangement 1 including a PCB 2, here illustrated as a LED board with LEDs 3 mounted thereon. The PCB 2 provided with a plurality of through holes 4, here including a set of holes in a pattern conformant with the ZHAGA standard. The PCB arrangement 1 further includes a set of fasteners, hereon referred to as clips 5. In the illustrated example, the arrangement includes one fastener for each ZHAGA hole.

The PCB 2 is mounted to a relatively thin support plate 6, e.g. formed as a plate of plastic or metal. The support has a thickness in the same order as the PCB. By way of example, a typical thickness of the PCB 2 is 1.6 mm, while a steel support plate may be 1.7 mm or 0.5 mm thick. The support 6 has a plurality of openings, here illustrated as through openings 7.

According to the present invention, the fasteners 5 are snap-fit (or click-on) fasteners, hereon referred to as “clips” 5. For this purpose, each clip 5 has a fixating portion 11 which is compressible against spring action and an abutment portion 12 connected to the fixating portion. When the fasteners 5 in FIG. 1 are introduced into the holes 4 and the openings 7, the fixating portion 11 is compressed to pass through the hole and allowed to expand on an opposite side of the hole so as to snap fit in the hole, while the abutment portion 12 abuts against the upper surface 2a of the PCB 2. The PCB is thereby attached to the support plate 6.

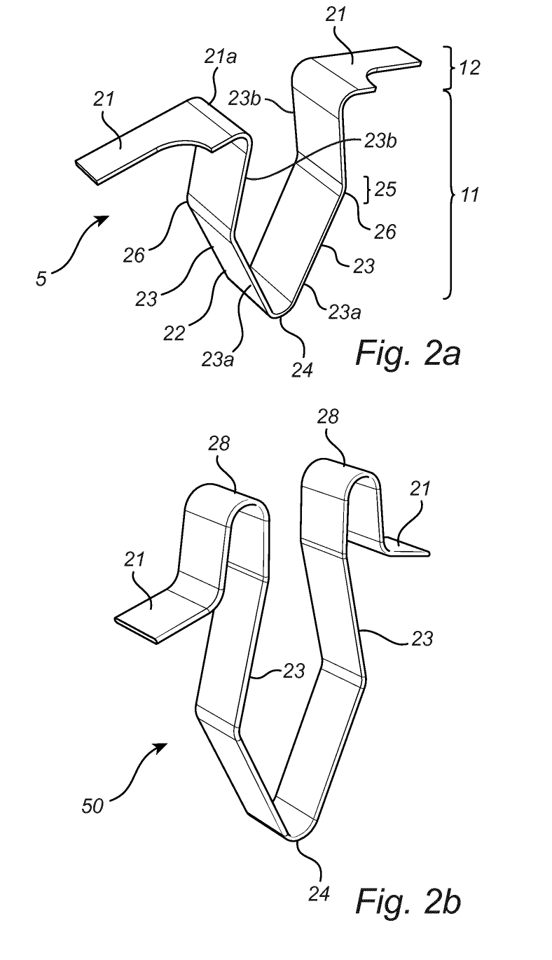

Some embodiments of the clips 5 and their function will now be described in more detail with reference to FIGS. 2-4.

The clip 5 in FIG. 2a is formed from a flattened metal wire which has been bent to a shape as shown in FIG. 2a. By using a flattened wire, the edges of the clip 5 are smooth and rounded. Alternatively, the clip 5 could be made from a flat ribbon material, but may then require rounding of the edges. The flattened metal wire is preferably heat treated after bending, so as to reset the elasticity of the metal as it was before bending. This increases the flexibility of the clip.

In the clip 5 in FIG. 2a, the abutment portion 12 is formed by the two flat flaps 21, extending out from the clip 5. The fixating portion 11 is formed by the generally U- or V-shaped segment of wire 22 connecting the two flaps 21. The wire segment 22 has two legs 23 extending between a common flexing point 24 and the central facing end 21a of each respective flap 21. Each leg 23 has a convex shape, so that the fixating portion 21 has a radially protruding section 25 which has a larger cross section than the rest of the fixating portion. In the illustrated example, this protruding section is formed by a knee 26 in each leg 23.

If the combined thickness of the PCB 2 and support 6 is less than the distance between the protruding section 25 (here the knee 26) and the abutment portion 11, then the clip will “snap” in place when the protruding portion is pressed beyond the end of the hole/opening. This will create a secure snap fit.

The size of the clip is preferably such that the central ends 21a of the flaps facing each other will make contact when the clip is pushed into, or pulled out of, the hole. This increases the force required to remove the clip, and thus the reliability of the mounting. Further, the shape of the clip 5 ensures that the force required to push the clip into a hole is smaller than the force required to pull it out of the same hole. More specifically, the lower segments 23a of each leg (i.e. between the knee 26 and the flexing point 24) are longer than upper segments 23b of each leg (i.e. between the flap 21 and the knee 26). Also, when the legs 23 are pushed together, during compression of the fixating portion, the angle between the lower segments 23b and the walls of the hole is reduced (lower force), while the angle between the upper segments 23a and the walls of the hole is increased (greater force).

Even though a larger force is required to remove the PCB from the support, it is still possible without damaging the fasteners. This is especially the case as it is possible to separate the PCB a certain distance from the support, allowing a user to insert fingers or a tool between the PCB and support in order to more effectively apply a force.

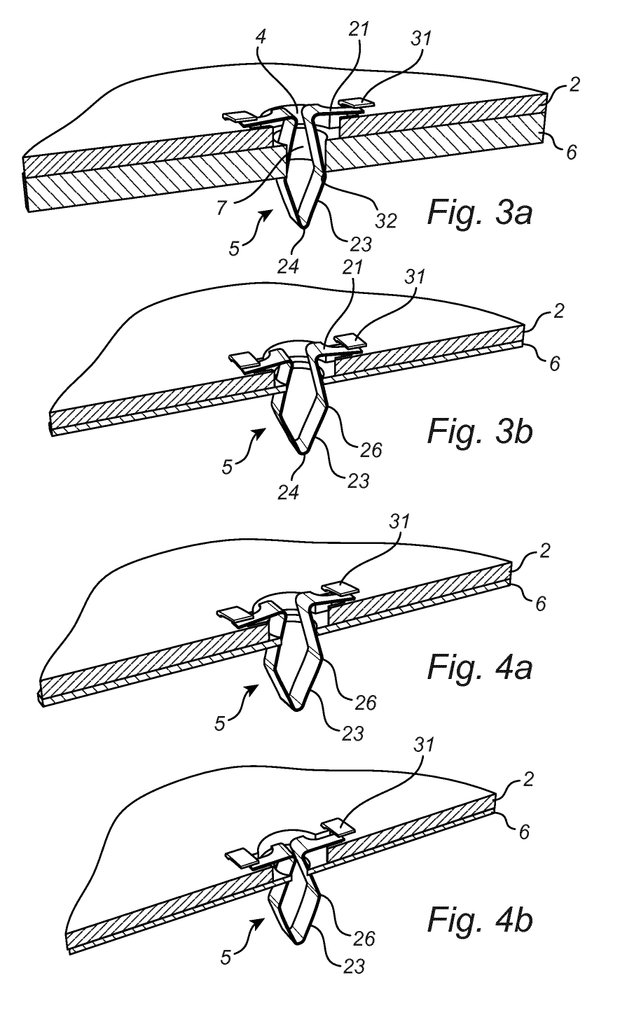

The clip 5 in FIG. 2a may be pre-assembled to the PCB 2, to make attachment to the support 6 very easy. In order for the legs 23 to be compressible towards each other, the flaps 21 are not necessarily fixedly attached to the PCB surface 2a. Instead, they may be secured by a suitable element, e.g. a surface mounted component 31, which prevents movement in the Z-direction (away from the PCB surface) but allows movement in the plane of the PCB. Such mounting is illustrated in the following FIGS. 3-4. The flexibility in the plane of the PCB 2 allows easy alignment of the clip 5 with the hole 4 and opening 7. Thereby, the snap-on effect of the clip 5 can be achieved even if the hole is not perfectly aligned with the opening.

As an alternative solution (not shown), one flap 21 is securely attached to the PCB (e.g. soldered) while the other flap 21 is held in place by a component 31. In many situations, this solution will provide satisfactory flexibility although for longer PCBs the tolerances of the hole size and position may need to be improved.

In order to allow a completely fixed mounting to the PCB, the clip 50 in FIG. 2b has two additional curved wire segments 28, extending between each leg 23 and each flap 21. These curved segments 28 ensure that the legs have a certain freedom to move towards each others, even when both flaps 21 are completely fixed to the PCB surface 2a (e.g. soldered in place). The curved segments 28 also provide a physical separation between the PCB 2 and its components and any object placed on top of the PCB.

FIGS. 3-4 illustrate various examples of a clip 5, held in place by two holding elements 31, securing a PCB 2 to a support 6. The elements 31 may be suitable surface mounted components, e.g. resistors. The examples illustrate the capability of the clip 5 to function also for large tolerances, making it very versatile.

In FIG. 3a, the support 6 has a very similar thickness as the PCB, while in FIG. 3b the support is significantly thinner than the PCB. As examples, the PCB may be 1.6 mm thick, and the supports may be 1.7 mm and 0.5 mm respectively. In both examples, the lower edge 32 of the combined hole 4, 7 meets the legs 23 of the clip 5 above the knee 26. However, in FIG. 3a, where the lower edge 32 of the combined hole is closer to the knee 26, the legs 23 will be pressed more closely together than in FIG. 3b. As the elements 31 do not fixate the flaps 21 in the plane of the PCB, the flaps 21 are allowed to move with the legs 23 and are closer together in FIG. 3a than in FIG. 3b.

In FIGS. 4a and 4b, the thickness of the support 6 is the same. Instead, the diameter of the hole 7 in the support is different. By way of example, the hole in FIG. 4a is 4.1 mm, while the hole in FIG. 4b is only 3.2 mm. As a consequence, the legs 23 of the clip in FIG. 4b are pressed more closely together. Again, the flaps 21 are allowed to move towards each other, as they are not fixated by the elements 31.

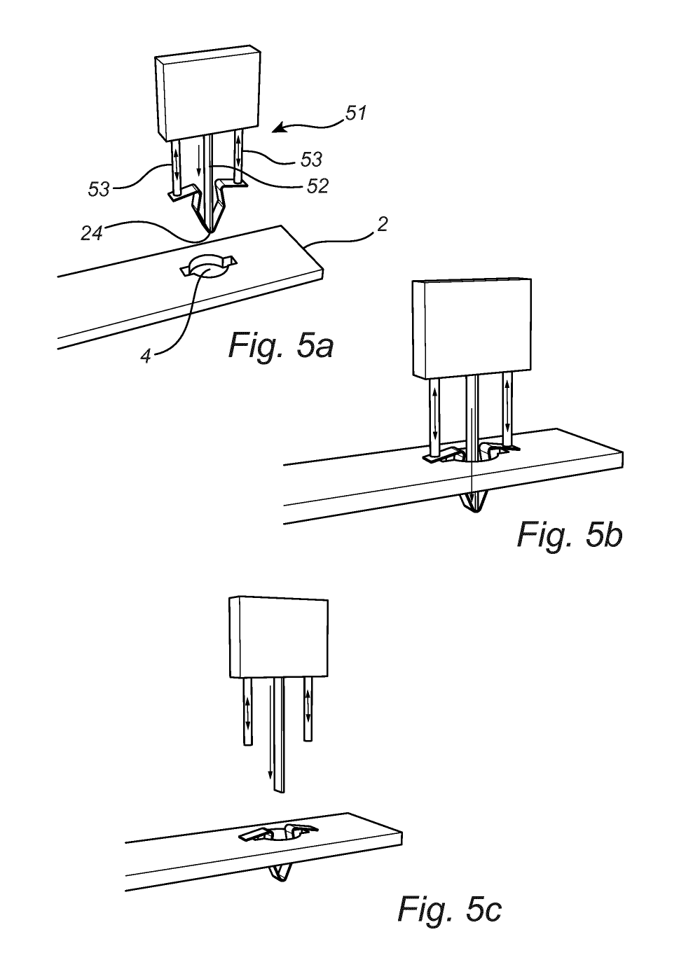

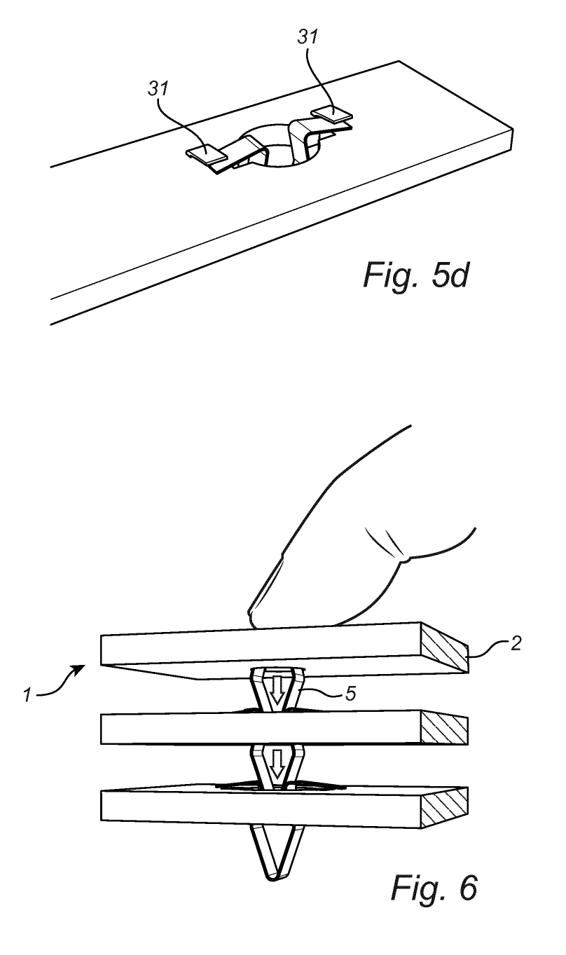

FIG. 5a-d schematically illustrates pre-mounting of clips 5 in a hole 4 of a PCB 2. First, in step 5a, a clip 5 is picked up by a mounting tool 51 having three prongs 52, 53. A first, central prong 52 is longer than the others, and abuts the lower end of the fixating portion 11 of the clip (i.e. in the flexing point 24). The other two prongs 53 are shorter than the first prong 52, and abut against the upper surface of the two flaps 21, respectively. In FIG. 5b, the tool 51 presses the clip 5 through the hole 4, until the clip snaps in place. In FIG. 5c, the tool is lifted, while the clip 5 remains in the hole 4. In FIG. 5d, two SMT components are mounted so as to partly overlap with the flaps 21, thereby fixating the flaps (and the clip 5) in the z-direction, while allowing movement in the plane of the PCB. FIG. 6 illustrates how several PCBs 2 with pre-mounted fasteners 5 can be stacked on top of each other. As shown in FIG. 6, the lower end 24 of a fastener 5 will rest between the two flaps 21 of an underlying fastener 5. This provides a combined effect. First, the two flaps provide an abutment that ensures a certain separation between the PCBs 2. Secondly, the point 24 forces the flaps 21 apart, thereby even further increasing the snap-on effect, and even harder securing the fastener.

The person skilled in the art realizes that the present invention by no means is limited to the preferred embodiments described above. On the contrary, many modifications and variations are possible within the scope of the appended claims. For example, the shape of the fasteners may be different, as long as the desired snap-on functionality is achieved. Also, the fasteners may be mounted using different techniques than SMT.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A PCB assembly, comprising:
a PCB having a set of through holes, and
at least one fastener configured to be introduced into one of said holes, the fastener is a snap on fastener having an abutment portion connected to a fixating portion, the fixating portion having a protruding section which is compressible against a spring force,
characterized in that a distance between the abutment portion and the protruding section is larger than a thickness of the PCB, such that, when the fixating portion is introduced into said hole, the protruding section is compressed to pass through the hole and allowed to expand on an opposite side of the hole so as to snap fit in the hole, while the abutment portion abuts against a surface of the PCB,
wherein the fastener is formed of a single flattened metal wire and,
wherein the abutment portion is formed by two flaps formed by the two ends of the wire, at least one flap being secured to the PCB by a suitable element.

2. The PCB assembly according to claim 1, wherein the fastener is designed such that a force required to push the fastener into a hole is smaller than a force required to pull the fastener out of the same hole.

3. The PCB assembly according to claim 1, wherein the suitable element is a surface mounted component.

4. The PCB assembly according to claim 1, wherein one flap is securely attached to the PCB while the other flap 21 is held in place by the suitable element.

5. The PCB assembly according to claim 1, wherein the fixating portion is formed by a generally U-shaped segment of wire connecting the two flaps, wherein the U-shaped segment has two legs extending between a common flexing point and a respective flap, wherein each leg has a convex shape to form the protruding section.

6. The PCB assembly according to claim 1, attached to a support plate having a set of openings aligned with the holes in the PCB, wherein said fasteners have been introduced into said holes and corresponding openings in the support, thereby securing the PCB to the support plate.

7. The PCB assembly according to claim 1, wherein each fastener is pre-mounted in one of said holes.

8. A stack of PCB assemblies according to claim 7, including at least a first PCB assembly resting on a second PCB assembly, wherein a distal end of the fixating portion of each fastener of the first PCB assembly rests on the abutment portion of a corresponding fastener of the second PCB.

9. A method for mounting a PCB to a support plate, the PCB having a set of through holes, and the support plate having a set of openings aligned with the holes in the PCB, the method comprising:
providing a set of snap-on fasteners, each fastener having an abutment portion connected to a fixating portion, the abutment portion is formed by two flaps and the fixating portion having a protruding section which is compressible against a spring force,
pre-mounting one of said fasteners in each hole in the PCB, by introduced the fixating portion into said hole such that the protruding section is compressed to pass through the hole and allowed to expand on an opposite side of the hole and snap fit in the hole, while the abutment portion abuts against a surface of the PCB,
aligning each fastener with a corresponding opening in the support plate, and
applying pressure on each fastener, such that the fixating portion is pressed through the opening in the support plate and allowed to expand on an opposite side of the opening so as to snap fit in the opening, thereby securing the PCB to the support plate, and securing the fastener with at least one flap to the PCB by a suitable element.

10. The method according to claim 9, wherein the fasteners are pre-mounted using surface mounting technology, SMT, processing.
